(19) United States
(12) Patent Application Publication
(10) Pub. No.: US 2026/0075889 A1
(43) Pub. Date: Mar. 12, 2026

(54) HYBRID ISOLATION PILLARS

(71) Applicant: International Business Machines Corporation, Armonk, NY (US)

(72) Inventors: Susan Ng Emans, Albany, NY (US); Ruilong Xie, Niskayuna, NY (US); Julien Frougier, Albany, NY (US); HUIMEI ZHOU, Albany, NY (US); Ravikumar Ramachandran, Pleasantville, NY (US); Kisik Choi, Watervliet, NY (US); Effendi Leobandung, Stormville, NY (US)

(21) Appl. No.: 18/828,659

(22) Filed: Sep. 9, 2024

(51) Int. Cl. H01L 29/06; H01L 27/092; H01L 29/08; H01L 29/423; H01L 29/775; H01L 29/786

(52) U.S. Cl. CPC H10D 62/115; H10D 30/43; H10D 30/6735; H10D 30/6757; H10D 62/121; H10D 62/151; H10D 84/85

(57) ABSTRACT

A semiconductor IC device includes a hybrid isolation pillar that has a first isolation pillar and a second isolation pillar. The semiconductor IC device includes a source/drain region in direct contact with the first isolation pillar and in direct contact with the second isolation pillar. The first isolation pillar may be composed of a same or different material relative to the material of the second isolation pillar. The source/drain region may be confined by the first isolation pillar and the second isolation pillar. The hybrid isolation pillar may reduce parasitic capacitance and may reduce a pitch between a n-type transistor and a p-type transistor and may reduce a pitch between the same type transistors within a transistor cell.

### BACKGROUND

Semiconductor integrated circuit (IC) devices are increasingly scaled smaller and smaller in size. One type of a transistor that may be utilized by such scaled semiconductor IC devices is a forksheet transistor. A forksheet transistor typically includes channels and source and drain regions of different transistors that are separated by an isolation pillar. The isolation pillar enables a relatively closer transistor pitch, which shrinks the size of the semiconductor IC device.

### SUMMARY

In an embodiment of the disclosure, a semiconductor IC device is presented. The semiconductor IC device includes a first isolation pillar, a second isolation pillar, and a source/drain region in direct contact with the first isolation pillar and in direct contact with the second isolation pillar.

In an embodiment of the disclosure, another semiconductor IC device is presented. The semiconductor IC device includes a first transistor with a first source/drain region and a plurality of first nanosheet channels. The semiconductor IC device further includes a second transistor with a second source/drain region. semiconductor IC device further includes a first isolation pillar in direct contact with the first source/drain region and in direct contact with each of the plurality of first nanosheet channels. The semiconductor IC device further includes a second isolation pillar in direct contact with the first source/drain region and in direct contact with the second source/drain region.

In an embodiment of the disclosure, a semiconductor IC device is presented. The semiconductor IC device includes a first source/drain region, a second source/drain region, a first isolation pillar in direct contact with a first sidewall of the first source/drain region, a second isolation pillar in direct contact with a second sidewall of the first source/drain region and in direct contact with a first sidewall of the second source/drain region, and a third isolation pillar in direct contact with a second sidewall of the second source/drain region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross-section views of a semiconductor IC device that includes hybrid isolation pillars, according to one or more embodiments of the disclosure.

FIG. 2 depicts a partial structure top-down view of an illustrative semiconductor IC device, according to one or more embodiments of the disclosure.

FIG. 3 through FIG. 17 depict various fabrication structure cross-section views of an illustrative semiconductor IC device that includes hybrid isolation pillars, according to one or more embodiments of the disclosure.

FIG. 18 depicts a method of fabricating a semiconductor IC device that includes hybrid isolation pillars, according to one or more embodiments of the disclosure.

### DETAILED DESCRIPTION

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a forksheet FET. A forksheet FET typically includes channels and source and drain regions of different transistors that are separated by an isolation pillar. The isolation pillar enables a relatively closer transistor pitch, which shrinks the size of the semiconductor IC device.

The flowcharts and cross-sectional diagrams in the drawings illustrate a method of fabricating a semiconductor IC device, such as a processor, field programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 10:1 or greater.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, the forksheet FET provides a relatively small FET footprint by forming the channel region as a series of vertically stacked nanolayers. In a forksheet configuration, one or more nanolayers extend from the isolation pillar and serve as the channel. A gate surrounds the exposed surfaces of the stacked nanolayers and regulates electron flow through the nanolayers between the source and drain regions. Forksheet FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

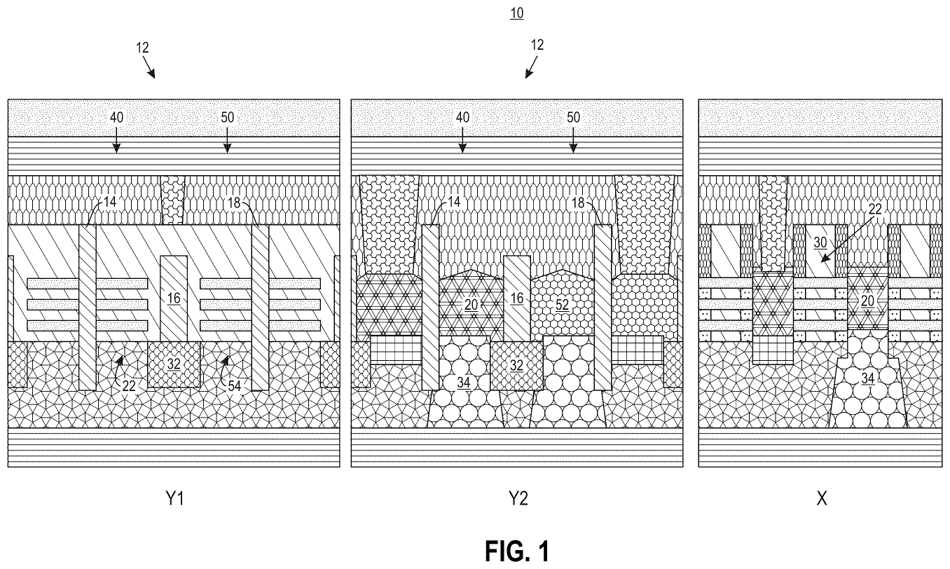

FIG. 1 depicts cross-section views of a semiconductor IC device 10 that includes hybrid isolation pillars 12, which may include, for example, a first isolation pillar 14 and a second isolation pillar 16. In an illustrative embodiment, semiconductor IC device 10 includes the first isolation pillar 14 and the second isolation pillar. The semiconductor IC device 10 further includes a source/drain region 20 in direct contact with the first isolation pillar 14 and in direct contact with the second isolation pillar 16.

In an example, a top surface of the first isolation pillar 14 is above a top surface of the second isolation pillar 16. In an example, a bottom surface of the first isolation pillar 14 is below a bottom surface of the second isolation pillar 16.

In an example, the semiconductor IC device 10 further includes a plurality of nanosheet channels 22 each in direct contact with the source/drain region 20 and each in direct contact first isolation pillar 14.

In an example, the semiconductor IC device 10 further includes a gate structure 30 in direct contact with the plurality of nanosheet channels 22, in direct contact with the first isolation pillar 14, and in direct contact with the second isolation pillar 16.

In an example, the top surface of the first isolation pillar 14 is substantially coplanar with a top surface of the gate structure 30. In an example, the semiconductor IC device 10 further includes a shallow trench isolation (STI) region 32 below the second isolation pillar 16.

In an example, the semiconductor IC device 10 further includes a backside contact 34 in direct contact with the source/drain region 20, in direct contact with the first isolation pillar 14, and in direct contact with the STI region 32.

In an example, the first isolation pillar 14 is composed of a first dielectric material and wherein the second isolation pillar 16 is composed of a second dielectric material that is different than the first dielectric material. For clarity, in an alternative example, the first isolation pillar 14 and the second isolation pillar 16 are composed the same or substantially the same material.

In an illustrative embodiment, another instance of semiconductor IC device 10 is presented. The semiconductor IC device includes a first transistor 40 that includes the first source/drain region 20 and the plurality of first nanosheet channels 22. The semiconductor IC device further includes a second transistor 50 that includes a second source/drain region 52. The semiconductor IC device further includes the first isolation pillar 14 in direct contact with the first source/drain region 20 and in direct contact with each of the plurality of first nanosheet channels 22. The semiconductor IC device further includes the second isolation pillar 16 in direct contact with the first source/drain region 20 and in direct contact with the second source/drain region 52.

In an example, the semiconductor IC device 10 further includes a plurality of second nanosheet channels 54 each in direct contact with the second source/drain region 52.

In an example, the semiconductor IC device 10 further includes the gate structure 30 in direct contact with the plurality of first nanosheet channels 22, in direct contact with the plurality of second nanosheet channels 54, in direct contact with the first isolation pillar 14, and in direct contact with the second isolation pillar 16.

In an illustrative embodiment, another instance of semiconductor IC device 10 is presented. The semiconductor IC device 10 includes the first source/drain region 20, the second source/drain region 52, the first isolation pillar 14 in direct contact with a first sidewall of the first source/drain region 20, a second isolation pillar 16 in direct contact with a second sidewall of the first source/drain region 20 and in direct contact with a first sidewall of the second source/drain region 52, and a third isolation pillar 18 in direct contact with a second sidewall of the second source/drain region 52.

In an example, a bottom surface of the first isolation pillar 14 is below a bottom surface of the second isolation pillar 16 and wherein the bottom surface of the first isolation pillar 16 is substantially coplanar with a bottom surface of the third isolation pillar 18.

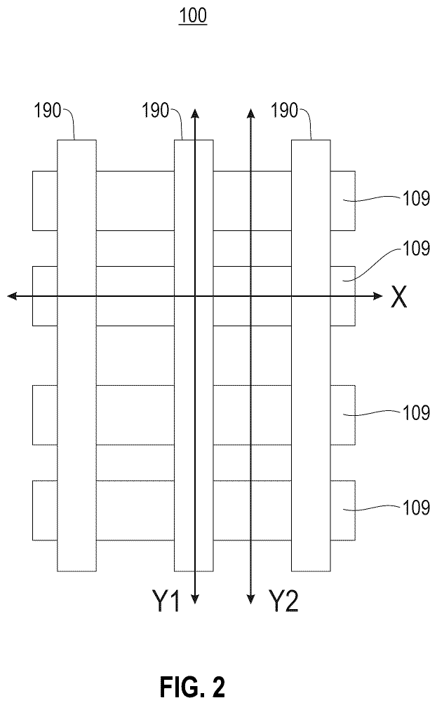

FIG. 2 depicts a partial top-down view of a semiconductor IC device 100 that includes hybrid isolation pillars, according to embodiments of the disclosure. As currently depicted, semiconductor IC device 100 includes nanolayer rows 109 and replacement gate structures 190. FIG. 2 also depicts cross-sectional planes of the various cross-sectional views of at least some of the drawings. The X cross-sectional plane is through a nanolayer row 109 and across replacement gate structures 190. The Y1 cross-sectional plane is through a replacement gate structure 190 and across nanolayer rows 109. The Y2 cross-sectional plane between replacement gate structures 190 and across nanolayer rows 109.

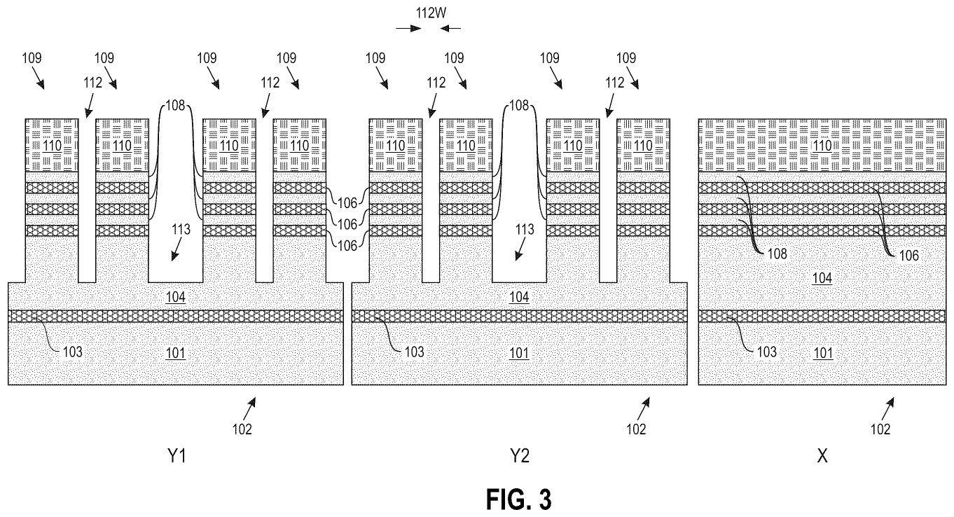

FIG. 3 depicts initial fabrication structure cross-section views of semiconductor IC device 100 that includes hybrid isolation pillars. At the present fabrication stage, semiconductor IC device 100 may include a substrate structure 102, nanolayer rows 109 which may include an alternating series of active nanolayers 108 and sacrificial nanolayers 106, a mask 110, and/or one or more isolation pillar openings 112.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In another example, the substrate structure may include an upper substrate 104, a lower substrate 101, and an etch stop layer 103 between the upper substrate 104 and the lower substrate 101. The upper substrate 104 and the lower substrate 101 may be comprised of any suitable material(s) including those listed above, and the etch stop layer 103 may be a dielectric material with etch selectivity to one or both the upper substrate 104 and/or the lower substrate 101. In one example, the etch stop layer 103 may be an oxide and the substrate structure 102 may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 104 may be composed of Si and may be epitaxially grown from the top surface of etch stop layer 103.

The illustrative semiconductor IC device 100 may be further fabricated by forming nanolayers over the substrate structure by forming a series of alternating sacrificial nanolayers 106 and active nanolayers 108, thereupon. In certain examples, the bottommost sacrificial nanolayer 106 is initially formed directly on an upper surface of the substrate structure 102. In other examples, certain layer(s) may be formed between the upper surface of the substrate structure 102 and the bottommost sacrificial nanolayer 106.

The sacrificial nanolayers 106 can have Ge percentages ranging from 20% to 45%. In an implementation, the alternating active sacrificial nanolayer 106 and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the sacrificial nanolayers 106 and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between vertically adjacent active nanolayers 108) may range from 5 nm to 15 nm. However, the VSP must be of a sufficient value to accommodate the formation of a gate structure that is to be formed in the spaces created by later removal of respective portions of the sacrificial nanolayers 106.

Further, in the depicted fabrication stages, the nanolayers may be patterned into nanolayer rows 109. To form one or more nanolayer rows 109, a mask 110 may be formed on the uppermost nanolayer. The mask 110 may be comprised of any suitable mask material(s). The mask 110 may be patterned and used to perform the nanolayer row 109 patterning process. In the nanolayer row 109 patterning process, any suitable material removal process (e.g., reactive ion etching or RIE) may be used to remove portions of the alternating nanolayers down to the level of the substrate structure 102, or the like. Following the nanolayer row patterning process, the one or more nanolayer rows 109 are formed.

The removal of undesired portion(s) of the nanolayers may further remove undesired portions of substrate structure 102 that are adjacent to respective footprints of nanolayer rows 109 to form STI region openings 113. The etch may be timed or otherwise controlled to stop the removal of the substrate structure 102 such that the depth or bottom of the one or more STI region openings 113 has a predetermined or desired dimension. For example, the depth or bottom of the one or more STI region openings 113 may be above the etch stop layer 103.

As depicted, the nanolayer rows 109 patterning process may form one or more isolation pillar opening(s) 112 that between adjacent nanolayer rows 109. The isolation pillar opening(s) 112 horizontal dimension 112W may be chosen so as to adequately electrically isolate the adjacent nanolayer rows 109 when a predetermined dielectric or isolation material with a predetermined dielectric constant is deposited therein. The depth of the isolation pillar opening(s) 112 may be controlled to be below the top surface of the substrate structure 102. For example, the etch utilized to form the isolation pillar opening(s) 112 may be controlled stop the removal of the substrate structure 102 such that the depth or bottom of the one or more isolation pillar opening(s) 112 has a predetermined or desired dimension. For example, the depth or bottom of the one or more isolation pillar opening(s) 112 may be above the etch stop layer 103. In a particular example, the well or bottom surfaces of the isolation pillar opening(s) 112 and the STI region opening(s) 113 may be substantially coplanar and may be formed in the same or sequential processes.

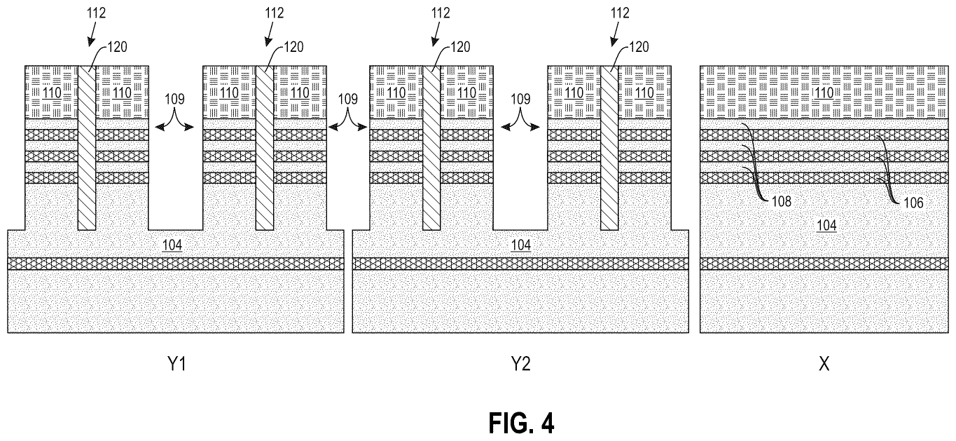

FIG. 4 depicts a fabrication structure cross-section view of the semiconductor IC device 100 that includes hybrid isolation pillars, according to one or more embodiments of the disclosure. In the depicted fabrication stage, isolation pillar 120 may be formed.

In an example, isolation pillar 120 may be formed by forming an isolation pillar layer to a thickness above the top surface of the mask 110 filling the isolation pillar opening 112. For clarity, within the isolation pillar opening 112, the isolation pillar layer may be formed directly upon respective sidewalls of the sacrificial nanolayer 106, directly upon respective sidewalls of the active nanolayers 108, directly upon the mask 110, and directly upon the substrate structure 102.

Excess portion(s) of isolation pillar layer may be removed by a substrative removal technique, such as an isotropic etch. The subtractive removal technique may generally remove the portion(s) of the isolation pillar layer that are not pinched-off (i.e., located within respective isolation pillar opening(s) 112). For example, as depicted, the subtractive removal technique may remove the isolation pillar layer on respective outer sidewall(s) of the nanolayer rows 109 (e.g., those sidewalls of the nanolayer rows 109 that face the STI region openings 113, etc.), may remove the isolation pillar layer upon the substrate structure 102 within the STI openings 113, may remove the isolation pillar layer upon respective outer sidewalls and upper surfaces of the mask 110, or the like. The isolation pillar layer that remains within the isolation pillar opening 112 may generally form the isolation pillar 120.

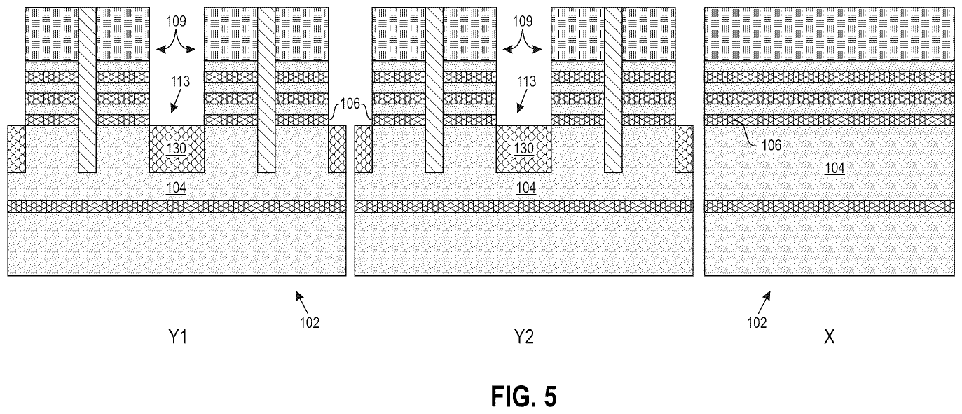

FIG. 5 depicts a fabrication structure cross-section view of the semiconductor IC device 100 that includes hybrid isolation pillars, according to one or more embodiments of the disclosure. In the depicted fabrication stage, STI regions 130 may be formed.

The STI regions 130 may be formed upon and/or within the substrate structure 102 within a respective STI region opening 113. The STI regions 130 may be formed by depositing electrical dielectric material(s) adjacent to the one or more nanolayer rows 109 within STI region opening 113. A top surface of the one or more STI regions 130 may be substantially coplanar with or below a top surface of the substrate structure 102, such as the top surface of the upper substrate 104. In some implementations, further fabrication operations may generally remove portions of the STI regions 130 (e.g., sacrificial gate removal, replacement gate fabrication pre-clean, etc.), such that the top surface of the STI region 130 is below the top surface of the substrate structure 102.

The one or more STI regions 130 may have a volume and/or geometry that sufficiently electrically isolates components or features of neighboring transistors. For example, a particular STI region 130 may separate and/or electrically isolate a particular nanosheet row 109 from an adjacent nanosheet row 109, a particular STI region 130 may separate and/or electrically isolate a particular forksheet transistor from an adjacent forksheet transistor.

In an example, the STI region 130 may be formed by depositing a STI liner within the STI region opening 113. Subsequently, the STI region 130 may be further formed by depositing STI dielectric material upon the STI liner. A etch back, recess, or the like, may occur to remove undesired or over formed STI liner and/or STI dielectric material, such that the top surface of the STI region 130 is substantially coplanar with or below a bottom surface of the bottommost sacrificial nanolayer 106. The STI liner may be composed of but not limited to a nitride, low-K nitride (i.e., a nitride material with a lower dielectric constant relative to SiO₂), or the like. The STI dielectric material may be composed of but not limited to an oxide, low-K oxide (i.e., an oxide material with a lower dielectric constant relative to SiO₂), or the like.

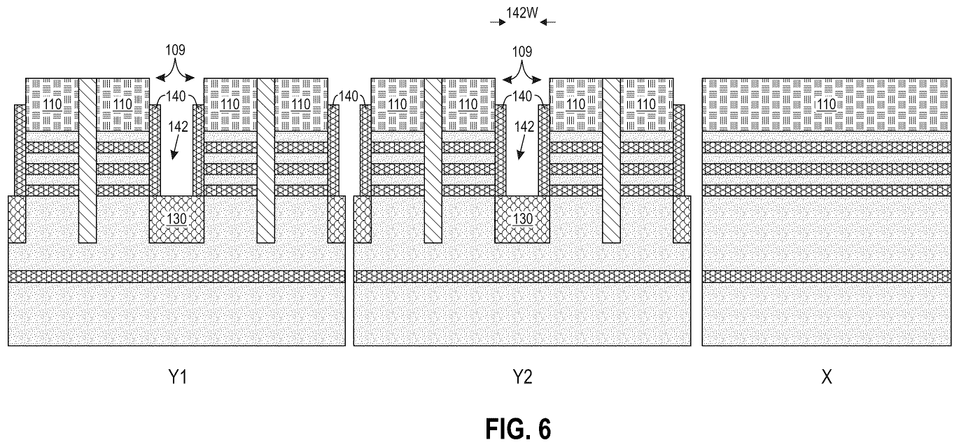

FIG. 6 depicts a fabrication structure cross-section view of the semiconductor IC device 100 that includes hybrid isolation pillars, according to one or more embodiments of the disclosure. In the depicted fabrication stage, sacrificial spacers 140 may be formed.

The sacrificial spacers 140 may be formed by a conformal deposition of a dielectric material layer, that is the same or substantially similar to the material of the sacrificial nanolayers 106. The dielectric material layer may be deposited upon STI regions 130, upon nanolayer rows 109, and upon mask 110. Subsequently, undesired portions of dielectric material layer may be removed while desired portions the dielectric material layer may be retained and thereby form the sacrificial spacers 140. The undesired portions of dielectric material may be removed by a directional ion etch, such as a reactive ion etch (RIE). The RIE may remove exposed or unprotected horizontal portions of the dielectric material while retaining protected vertical portions of the dielectric material upon the nanolayer rows 109 to resultantly form the sacrificial spacers 140.

Adjacent sacrificial spacers 140 may effectively form an isolation pillar openings 142. The isolation pillar opening(s) 142 horizontal dimension 142W may be chosen so as to adequately electrically isolate the adjacent nanolayer rows 109 when a predetermined dielectric or isolation material with a predetermined dielectric constant is deposited therein. The depth of the isolation pillar opening(s) 142 may be controlled to be substantially coplanar with STI region 130. For example, the etch utilized to form the sacrificial spacers 140 may expose at least a portion of the STI region 130. In a particular example, the horizontal dimension 142W of the isolation pillar opening(s) 142 may be smaller than a horizontal dimension of the STI region 130 there below. For instance, the isolation pillar opening 142 may be inset within the top surface of the STI region associated therewith.

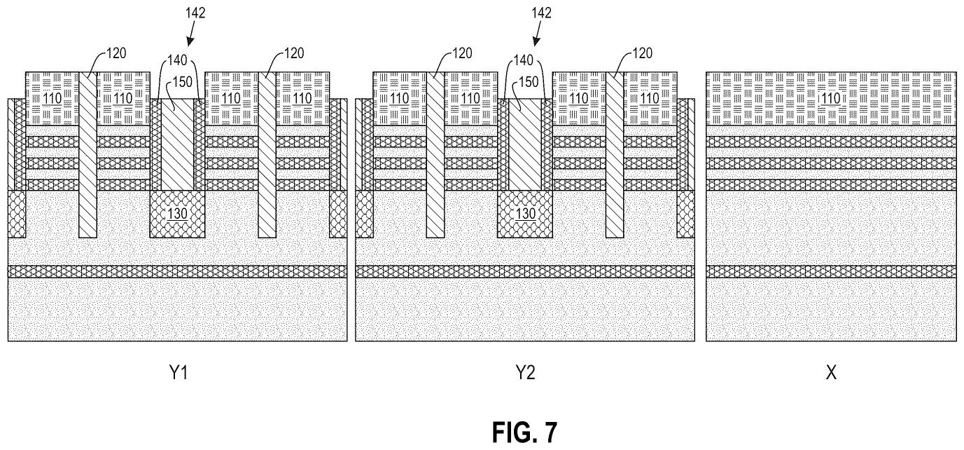

FIG. 7 depicts a fabrication structure cross-section view of the semiconductor IC device 100 that includes hybrid isolation pillars, according to one or more embodiments of the disclosure. In the depicted fabrication stage, isolation pillar 150 may be formed.

In an example, isolation pillar 150 may be formed by forming an isolation pillar layer to a thickness above the top surface of the mask 110 filling the isolation pillar opening 142. For clarity, within the isolation pillar opening 142, the isolation pillar layer may be formed directly upon the sacrificial spacers 140, directly upon the mask 110, and directly upon the STI region 130.

Excess portion(s) of isolation pillar layer may be removed by a substrative removal technique, such as an isotropic etch. The subtractive removal technique may generally remove the portion(s) of the isolation pillar layer that are not pinched-off (i.e., located within respective isolation pillar opening(s) 142). For example, as depicted, the subtractive removal technique may remove the isolation pillar layer upon the mask 110, upon the top surfaces of the sacrificial spacers 140, upon the top surfaces of the isolation pillar 120, or the like. The isolation pillar layer that remains within the isolation pillar opening 142 may generally form the isolation pillar 150. In an example, a top surface of the isolation pillar 150 may be inset between a top surface and bottom surface of the mask 110.

For clarity, the isolation pillar 150 may be composed of substantially the same dielectric material relative to the isolation pillar 120. Alternatively, the isolation pillar 150 may be composed of a relatively different dielectric material to the isolation pillar 120. In an example, a top surface of the isolation pillar 120 is above a top surface of the isolation pillar 150. In an example, a bottom surface of the isolation pillar 120 is below a bottom surface of the isolation pillar 150. In an example, a vertical dimension between the bottom surface of the isolation pillar 120 and the bottom surface of the isolation pillar 150 is substantially similar to the vertical dimension of STI region 130.

For clarity, in an example, a horizontal dimension of the isolation pillar 150 may be greater than a horizontal dimension of the isolation pillar 120. This may result due to geometrical requirements for the isolation pillar 150 to adequately separate or adequately electrically isolate adjacent transistors of different types and due to geometrical requirements for the isolation pillar 120 to adequately separate or adequately electrically isolate transistors of the same type. Subsequently, the mask 110 may be removed.

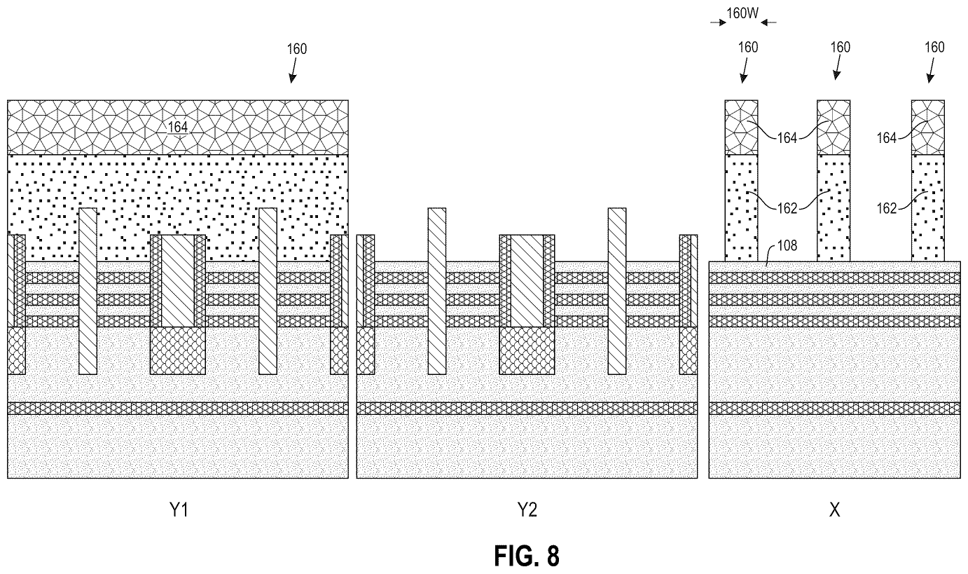

FIG. 8 depicts a fabrication structure cross-section view of the semiconductor IC device 100 that includes hybrid isolation pillars, according to one or more embodiments of the disclosure. In the depicted fabrication stage, sacrificial gate structures 160 may be formed.

The sacrificial gate structures 160 may include a sacrificial gate liner (not shown), a sacrificial gate 162, and a sacrificial gate cap 164. The sacrificial gate structures 160 may be formed by initially depositing a sacrificial gate liner layer (e.g., a dielectric, oxide, or the like) upon the one or more active nanolayers 108, upon and around the exposed portion of the isolation pillar 120, upon the isolation pillar 150, and upon the expose portions of the sacrificial spacer 140. The sacrificial gate structures 160 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the isolation pillar 120. The sacrificial gate structures 160 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 160 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 162, and the sacrificial gate cap 164, respectively, of each of the one or more sacrificial gate structures 160. The one or more sacrificial gate structures 160 can be formed on targeted regions or areas of semiconductor IC device 100 to define the gate length 160W of one or more transistors and to provide sacrificial material for yielding targeted transistor structure(s).

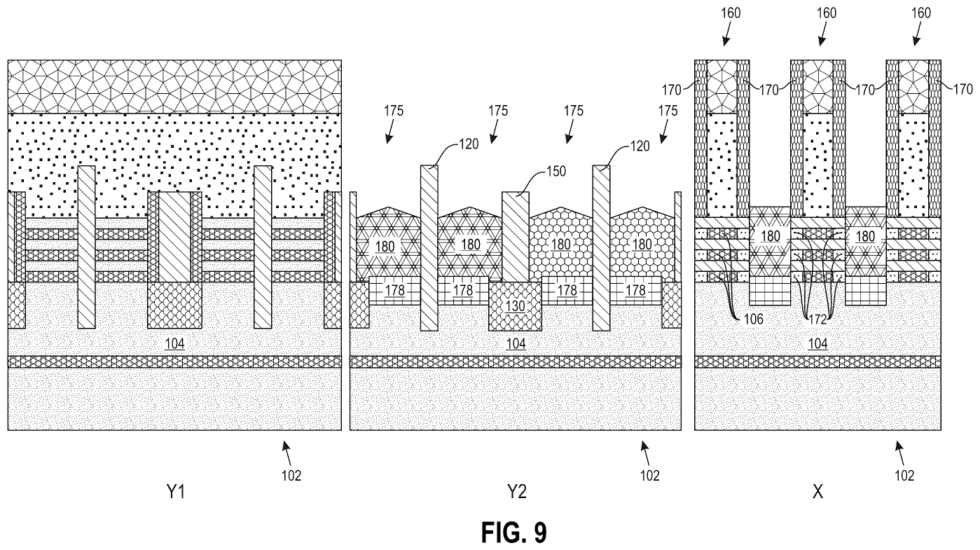

FIG. 9 depicts a fabrication structure cross-section view of the semiconductor IC device 100 that includes hybrid isolation pillars, according to one or more embodiments of the disclosure. In the depicted fabrication stage, gate spacers 170 may be formed, S/D region canyons 175 may be formed, sacrificial nanolayers 106 may be laterally indented, inner spacers 172 may be formed in the lateral indents, backside contact placeholders 178 may be formed, and respective source/drain (S/D) regions 180 may be formed.

The gate spacer(s) 170 may be formed by a conformal deposition of a dielectric material, such as silicon nitride, SiBCN, SiNC, SiN, SiCO, SiNOC, or a combination thereof, or the like, upon the one or more topmost active nanolayers 108, upon and around the exposed portion of the isolation pillar 120, upon the isolation pillar 150, upon the expose portions of the sacrificial spacer 140, and upon around the one or more sacrificial gate structures 160. Subsequently, undesired portions of dielectric material may be removed while desired portions the dielectric material may be retained and thereby form the gate spacers 170. The undesired portions of dielectric material may be removed by a directional ion etch, such as a reactive ion etch (RIE). The RIE may remove exposed or unprotected horizontal portions of the dielectric material while retaining protected vertical portions of the dielectric material to resultantly form the gate spacers 170.

The illustrated semiconductor IC device 100 may be further fabricated by forming S/D region canyons 175 within the one or more nanolayer rows 109 between gate spacers 170 of neighboring sacrificial gate structures 160. In other words, a single nanolayer row 109 may be separated, by one or more S/D region canyons 175, into multiple nanolayer stacks with each nanolayer stack located underneath a respective sacrificial gate structure 160 and associated gate spacer(s) 170.

The one or more S/D region canyons 175 may be formed by removing respective portions of the sacrificial nanolayers 106, active nanolayers 108, and sacrificial spacers 140 that are between gate spacers 170 of adjacent or neighboring sacrificial gate structures 160. The one or more S/D region canyons 175 may be initially formed to a depth to stop at the top surface of the substrate structure 102, the top surface of STI regions 130, or the like.

The undesired portions of sacrificial nanolayers 106, active nanolayers 108, and sacrificial spacers 140 may be removed by etching or other subtractive removal techniques. The top surface of the substrate structure 102 and/or STI regions 130 may be used as an etch stop or other etch parameters may be controlled to stop the material removal at the substrate structure. As the gate spacers 170 and the sacrificial gate structures 160 may be utilized to protect the underlying portions of sacrificial nanolayers 106 and active nanolayers 108, respective sidewalls of the resulting nanolayer stacks may be substantially coplanar and substantially vertical with the outer sidewalls of the gate spacers 170 there above.

As used herein, “substantially vertical” sidewalls deviate from a direction normal to a major surface (e.g., top surface, etc.) of the substrate structure 102 by less than 5°, e.g., 0°, 1°, 2°, 3°, 4°, or 5°, including ranges between any of the foregoing values.

The illustrated semiconductor IC device 100 may be further fabricated by forming horizontal or lateral indents within the sacrificial nanolayers 106 by laterally or horizontally removing respective portions of sacrificial nanolayers 106. The indents may be formed by a reactive ion etch (RIE) process, which can remove portions of the sacrificial nanolayers 106. The horizontal depth of the indents may be chosen to set a gate length for a replacement gate structure that is formed in place of one sacrificial gate structure 160. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below gate spacer 170).

The illustrated semiconductor IC device 100 may be further fabricated by next forming a respective inner spacer 172 within each indent. The one or more inner spacers 172 can be formed by ALD or CVD or any other suitable deposition technique that deposits a dielectric material within the indent(s), thereby forming the inner spacers 172. In some examples, the inner spacers 172 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 172, a directional etch process is performed to create substantially vertical sidewalls of the inner spacers 172 that are coplanar with the substantially vertical sidewalls of the active nanolayers 108 and/or of the gate spacers 170.

The illustrated semiconductor IC device 100 may be further fabricated by forming one or more backside contact placeholders 178 within the substrate structure 102 in between adjacent sacrificial gate structures 160 within a respective opening. In one example, a respective backside contact placeholder 178 may be formed in all opening location(s), such that a respective backside contact placeholder 178 is located underneath each S/D region.

If the S/D region canyons 175 are not of sufficient depth, the one or more backside contact placeholders 178 may be formed by forming one or more backside contact placeholder openings within the substrate structure 102 generally in between adjacent sacrificial gate structures 160 and below the prior respective S/D region canyons 175. The one or more backside contact placeholders 178 may be further formed by epitaxially growing an epitaxial material from exposed substrate structure 102 surface(s) within the one or more backside contact placeholder(s) openings. In an example, the epitaxial material of the one or more backside contact placeholders 178 may be chosen to be etch selective to the material of the S/D region(s), the material of the upper substrate 104, or the like.

In an example, (not shown) a barrier layer may be formed upon the backside contact placeholder 178 within the one or more backside contact placeholder(s) cavities. The barrier layer may be utilized to help protect or mask the associated backside contact placeholder 178 during the etching process(es). The barrier layer(s) may be epitaxially grown. For example, the one or more backside contact placeholders 178 may be SiGe and the barrier layer(s) may be Si.

The illustrated semiconductor IC device 100 may be further fabricated by forming a respective S/D region 180 upon the backside contact placeholder 178 within a S/D region canyon 175. For example, p-doped S/D regions 180 may be formed in a first formation sequence and n-doped S/D regions 180 may be formed in a second formation sequence, or vice versa.

Each S/D region 180 may form either a source or a drain, respectively, of a respective transistor and is connected to respective end surfaces of the active nanolayers 108. Each S/D region 180 is composed of a semiconductor material and a dopant. As used herein, a “source/drain” region can be a source region or a drain region depending on doping type and subsequent wiring and application of voltages during operation of the applicable transistor.

The semiconductor material that provides each of the S/D regions 180 may be composed of one of the semiconductor materials mentioned above for the substrate structure 102. For example, the semiconductor material that provides the S/D region 180 can be compositionally the same, or compositionally different from each active nanolayer 108. The dopant that is present in the S/D regions 180 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, include, but are not limited to, antimony, arsenic and phosphorous. When the semiconductor material is doped with a p-type dopant, the resulting S/D regions 180 may be referred to herein as being p-doped and when the semiconductor material is doped with a n-type dopant, the resulting S/D regions 180 may be referred to herein as being n-doped.

The S/D regions 180 may be epitaxially grown or formed. In some examples, the S/D regions 180 are formed by in-situ doped epitaxial growth. The use of an in-situ doping process is merely an example. For instance, one may instead employ an ex-situ process to introduce dopants into the S/D regions 180. Other doping techniques can be used to incorporate dopants in the S/D regions 180. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, S/D epitaxial growth conditions promote in-situ Boron doped SiGe for p-type transistor and phosphorus or arsenic doped silicon or Si:C for n-type transistors.

In some examples, the epitaxial growth that forms the S/D region 180 occurs or is promoted from the top surface of the substrate structure 102, or the like, while epitaxial growth may be limited or does not occur from neighboring STI regions 130.

In some implementations, epitaxial growth to form the one or more S/D regions 180 may overgrow above the upper surface of the sacrificial gate structure(s) 160 and be subsequently recessed such that the top surface of the S/D region(s) 180 may be substantially horizontal and above the top surface of the topmost active nanolayer 108 (e.g., to enable contact between the end surface of that active nanolayer 108 and the S/D region 180). In other implementations, the epitaxial grown crystalline surfaces (e.g., (111) diamond crystalline surfaces) of the S/D region(s) 180 may be maintained, as depicted in the Y2 cross-section.

For clarity, in the Y2 plane the S/D regions 180 may be directly connected, grown directly against, or the like, to at least the associated side surfaces of the isolation pillars 120 and isolation pillars 150. As such, the growth or formation of the S/D regions 180 may be confined by the isolation pillars 120 and isolation pillars 150.

For clarity, S/D regions 180 may directly contact the isolation pillar 150 and may further directly contact the associated STI region 130 due to the exposure of the STI region 130 due to the removal of the sacrificial spacer 140.

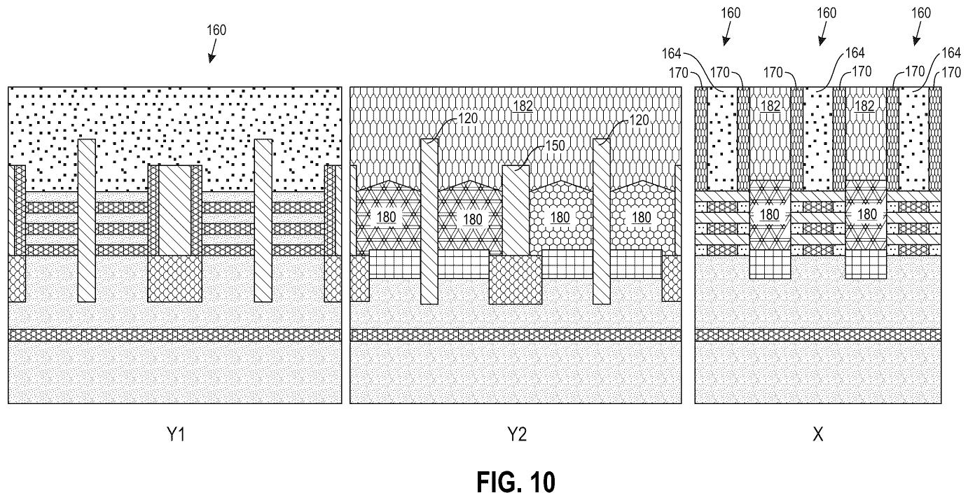

FIG. 10 depicts a fabrication structure cross-section view of the semiconductor IC device 100 that includes hybrid isolation pillars, according to one or more embodiments of the disclosure. In the depicted fabrication stage, interlayer dielectric (ILD) 182 may be formed. The ILD 182 may be formed by forming a blanket ILD over the S/D region(s) 180, over the gate spacers 170, and over the isolation pillar 120, over the isolation pillar 150, and/or the like.

The ILD 182 can be any suitable material, such as, for example, porous silicates, carbon doped oxides, silicon dioxides, silicon nitrides, silicon oxynitrides, OPL, or other dielectric materials. Any known manner of forming the ILD 182 can be utilized. The ILD 182 can be formed using, for example, CVD, PECVD, ALD, flowable CVD, spin-on dielectrics, or PVD.

In an example, the ILD 182 may be formed to a thickness above the top surface of the sacrificial gate structures 160. Subsequently, a planarization process, such as a CMP, may be performed to remove excess ILD 182 material and to remove the sacrificial gate caps 164 of the sacrificial gate structures 160, thereby exposing the sacrificial gate 162 thereunder. The planarization may also partially remove some of the sacrificial gates 162 or may at least expose the sacrificial gate 162 of the sacrificial gate structures 160. The CMP may create a substantially planar or substantially horizontal top surface for the semiconductor IC device 100. In other words, the respective top surfaces of ILD 182, gate spacers 170, sacrificial gate structures 160, may be substantially coplanar and/or substantially horizontal.

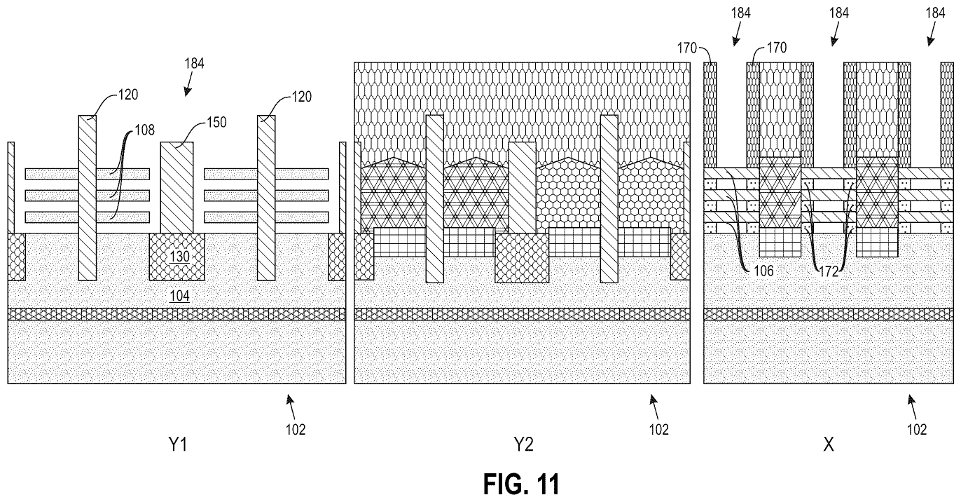

FIG. 11 depicts a fabrication structure cross-section view of the semiconductor IC device 100 that includes hybrid isolation pillars, according to one or more embodiments of the disclosure. In the depicted fabrication stage, respective replacement gate openings 184 may be formed by removing the remaining sacrificial gate structures 160 and the active nanolayers 108 may be released.

The sacrificial gate structures 160 may be removed by removing the sacrificial gate 162 and sacrificial gate oxide by a removal technique, such as one or more series of etches. For example, such removal may be accomplished by a wet chemical etching process in which one or more chemical etchants are used to remove the sacrificial gate 162 and sacrificial gate oxide of the sacrificial gate structures 160. Appropriate etchants may be used that remove the sacrificial gate 162 and/or sacrificial gate oxide selective to the gate spacers 170, active nanolayers 108, the sacrificial nanolayers 106, the STI regions 130, the inner spacers 172, the isolation pillar 120, the substrate structure 102, and the isolation pillar 150, or the like.

The active nanolayers 108 may be released by removing the sacrificial nanolayers 106 within the respective replacement gate openings 184. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 172, gate spacers 170, STI regions 130, isolation pillar 120, isolation pillar 150, substrate structure 102, or the like. After the removal of sacrificial nanolayers 106 void spaces may be formed above and/or below the active nanolayers 108.

FIG. 11 depicts a fabrication structure cross-section view of the semiconductor IC device 100 that includes hybrid isolation pillars, according to one or more embodiments of the disclosure. In the depicted fabrication stage, a replacement gate structure 190 is formed within the respective replacement gate openings 184 upon the isolation pillar 120, around the isolation pillar 150, around the active nanolayers 108.

The replacement gate structure(s) 190 may be formed by initially forming an interfacial layer (not shown) on the gate spacers 170, on the active nanolayers 108, on the inner spacers 172, on the substrate structure 102, on the STI regions 130, upon the isolation pillar 120, and upon the upon the isolation pillar 150, etc. that are interior to and/or upon the respective surfaces interior to the replacement gate openings 184. The interfacial layer can be deposited by any suitable techniques, such as ALD, CVD, PVD, thermal oxidation, combinations thereof, or other suitable techniques.

The replacement gate structure(s) 190 may be further formed by forming a high-κ layer (not shown) upon the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer. In other embodiments, the high-κ layer can include, e.g., Ti, Ag, Al, TiAlN, TaC, TaCN, TaSiN, Mn, Zr, TiN, TaN, Ru, Mo, Al, WN, Cu, W, or any suitable materials.

The replacement gate structure(s) 190 may be further formed by depositing a work function (WF) gate (not shown) upon the high-κ layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the transistor(s). The high-κ layer may separate the WF gate from the active nanolayers 108. Other metals that may be desired to further fine tune the effective work function (eWF) and/or to achieve a desired resistance value associated with current flow through the replacement gate structure 190 in the direction parallel to the plane of the active nanolayers 108.

The replacement gate structure(s) 190 may be further formed by depositing a conductive gate 192. In an example, when none of the previous replacement gate material(s) are utilized in the replacement gate structures 190, the conductive gate 192 may be formed upon the same or similar surfaces as those upon which the interfacial layer, described above, may be formed. In other examples, when one or more of the interfacial layer, the high-κ layer, the WF gate, or the like, are utilized in the replacement gate structures 190, the conductive gate 192 may be formed upon the most recent structural formation thereof.

The conductive gate 192 can be comprised of a conductor material and/or metal, such as but not limited to, e.g., tungsten, aluminum, ruthenium, rhodium, cobalt, copper, tantalum, titanium, carbon nanowire materials including graphene, or the like. The conductor material and/or metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 190 formation, the top surface of the semiconductor IC device 100 may be planarized by a planarization technique such as a CMP, mechanical grinding process, or the like. After the planarization technique, respective top surfaces of the ILD 182, gate spacers 170, replacement gate structures 190, isolation pillar 120, or the like, may be substantially horizontal and/or may be substantially coplanar.

For clarity, in some implementations, a top surface of the replacement gate structure 190 may be coplanar with or below the top surface of the isolation pillar 120 to form distinct gates. In other implementations, a top surface of the replacement gate structure 190 may be above the top surface of the isolation pillar 120 to form a shared replacement gate structure 190.

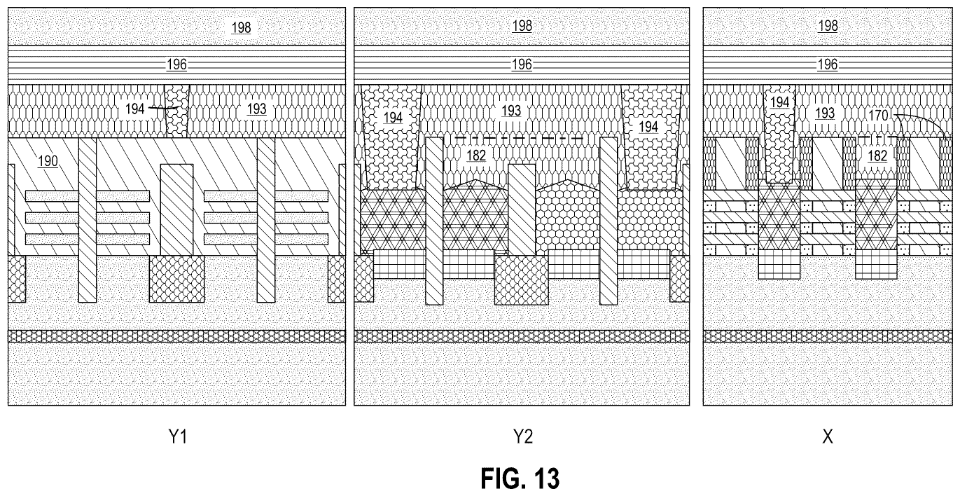

FIG. 13 depicts a fabrication structure cross-section view of the semiconductor IC device 100 that includes hybrid isolation pillars, according to one or more embodiments of the disclosure. In the depicted fabrication stage, a frontside contact ILD 193 may be formed, frontside contacts 194 may be formed, frontside back end of line (BEOL) network 196 may be formed, and a carrier wafer 198 may be attached.

The frontside contact ILD 193 may be formed upon respective top surfaces of replacement gate structure(s) 190, ILD 182, and gate spacers 140. The frontside contact ILD 193 may be formed by depositing a dielectric material, such as, for example, porous silicates, carbon doped oxides, silicon dioxides, silicon nitrides, silicon oxynitrides, or other dielectric materials.

The illustrated semiconductor IC device 100 may be further fabricated by next forming frontside contacts 194 within the frontside contact ILD 193 and the ILD 182. The frontside contacts 194 may be formed by patterning respective frontside contact openings within frontside contact ILD 193 and ILD 182, respectively, from the frontside (i.e., from above the semiconductor IC device 100, as depicted, downward to respective structures thereof). The frontside contact 194 may be in direct or indirect physical and electrical contact with respective regions, such as S/D region 180, replacement gate structure 190, or the like.

The frontside contacts 194 may be formed by initially forming frontside contact opening(s). The frontside contact(s) 194 may be further formed by depositing conductive material such as metal into the respective frontside contact opening(s). In an example, frontside contact(s) 194 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. Subsequently, the respective top surfaces of frontside contact(s) 194 and the frontside contact ILD 193 may be substantially horizontal and/or substantially coplanar. In embodiments, the frontside contact(s) 194 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., FEOL transistors, the BEOL is made up of interconnects and wiring, and the MOL is an interconnect between the FEOL and BEOL that includes material to prevent the diffusion of BEOL metals to FEOL devices.

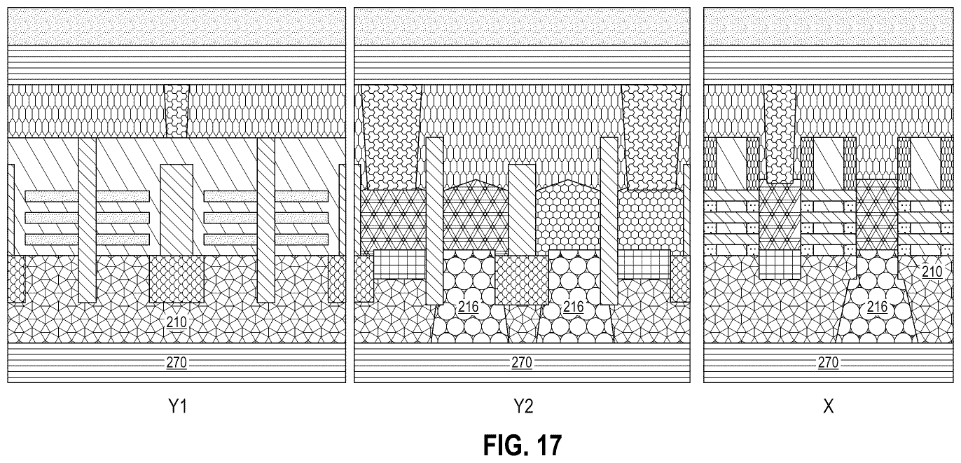

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), wires, vias and dielectric structures are formed. For modern IC processes, more than one metal layers may be added in the BEOL. In the present example, there are multiple BEOL levels each on opposites sides of the semiconductor IC device 100. First, a frontside BEOL network 196 is formed on the frontside of the semiconductor device 100. Subsequently, a backside BEOL network 270, as depicted in FIG. 17, is formed.

In the depicted example, the frontside BEOL network 196 is formed over the contact ILD 193 and upon the frontside contacts 194. Respective wires within the frontside BEOL network 196 may be electrically connected to the one or more S/D regions 180, to the one or more replacement gate structure(s) 190, or the like, by a respective frontside contact(s) 194. For example, respective wire(s) within the frontside BEOL network 196 may be electrically connected to appropriate S/D regions 180 by a frontside contact 194 and another and different group of respective wire(s) within the frontside BEOL network 196 may be electrically connected to appropriate replacement gate structures 190.

The frontside BEOL network 196 is located directly on the frontside surface of the MOL structure (e.g., contact ILD 193, frontside contact(s) 194, etc.). The frontside BEOL network 196 can include one or more dielectric material layers (including one of the dielectric materials mentioned above for the frontside ILD 182) and contains metal wires (the metal wires can be composed of any electrically conductive metal or electrically conductive metal alloy) embedded therein. In some embodiments, the frontside metal wires within the frontside BEOL network 196 are composed of Cu. The frontside BEOL network 196 can include “x” numbers of frontside metal levels, wherein “x” is an integer starting from 1. The frontside BEOL network 196 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by next bonding carrier wafer 198 to the frontside BEOL network 196. The carrier wafer 198 can include one of the semiconductor materials mentioned above for the semiconductor structure and the carrier wafer 198 may be attached to the semiconductor IC device 100 by a wafer-to-wafer bonding technique.

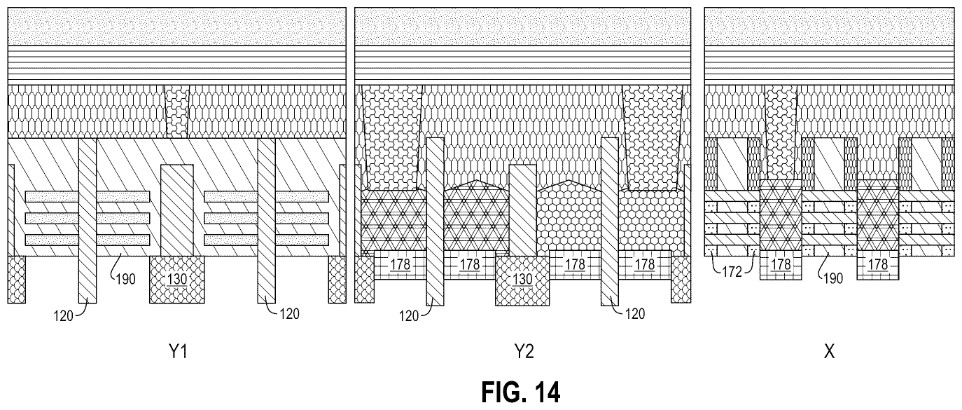

FIG. 14 depicts a fabrication structure cross-section view of the semiconductor IC device 100 that includes hybrid isolation pillars, according to one or more embodiments of the disclosure. In the depicted fabrication stage, substrate structure 102 is removed.

The substrate structure 102 may be removed by flipping the semiconductor IC device 100 (not shown) and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103. The etch stop layer 103 may be removed by a subtractive removal technique such as a CMP, dry and/or wet etch. Upon removal of the etch stop layer 103, the bottom surface upper substrate 104 is exposed. The removal of etch stop layer 103 may be selective to the material of upper substrate 104. For example, etch stop layer 103 is removed by an etch that utilizes upper substrate 104 as the etch stop.

The upper substrate 104 may be removed by one or more etch process(es). The etch may be timed or otherwise controlled to remove the material of substrate structure 102 selective to the STI regions 130, to the backside contact placeholders 178, to the isolation pillar 120, to the bottom most inner spacer 172, to the replacement gate structure 190, or the like.

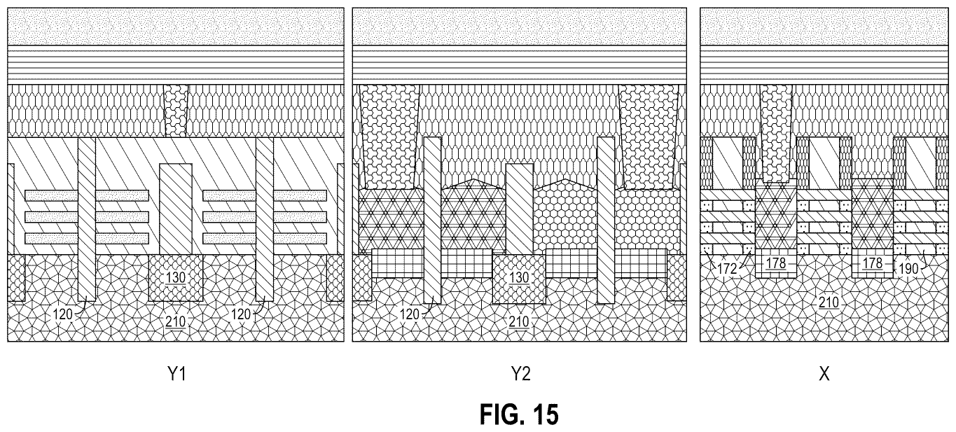

FIG. 15 depicts a fabrication structure cross-section view of the semiconductor IC device 100 that includes hybrid isolation pillars, according to one or more embodiments of the disclosure. In the depicted fabrication stage, backside ILD 210 may be formed upon the exposed backside of the semiconductor IC device 100.

The backside ILD 210 may be formed upon the respective exposed surfaces of the STI regions 130, the backside contact placeholders 178, the bottommost inner spacer 172, the replacement gate structure 190, and the like. The backside ILD 210 may be formed by depositing a dielectric material, such as, for example, porous silicates, carbon doped oxides, silicon dioxides, silicon nitrides, silicon oxynitrides, or other dielectric materials. In an example, the backside ILD 210 and the ILD 182 may be composed of the same material(s). Any appropriate deposition technique for forming the backside ILD 210 can be utilized. In an example, the backside ILD 210 may be formed to a thickness below the respective bottom surfaces of the STI regions 130 and/or below the bottom surface of the isolation pillar 120.

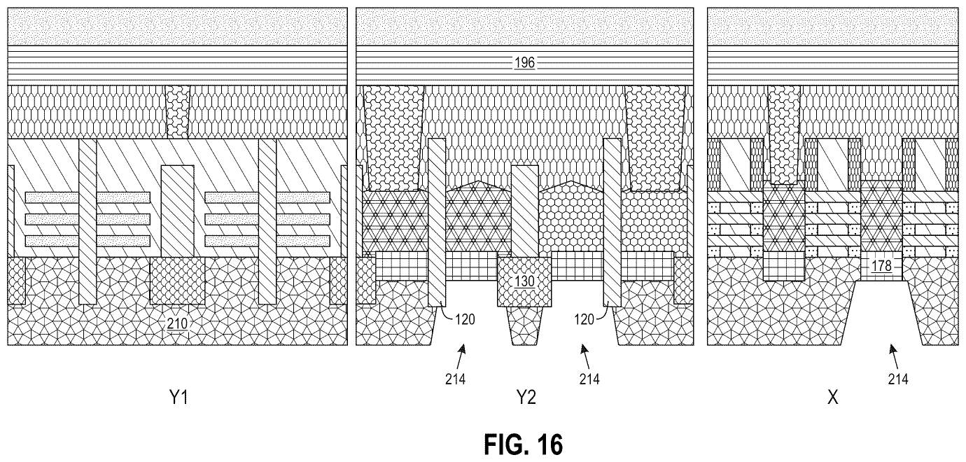

FIG. 16 depicts a fabrication structure cross-section view of the semiconductor IC device 100 that includes hybrid isolation pillars, according to one or more embodiments of the disclosure. In the depicted fabrication stage, backside contact opening(s) 214 may be formed.

The backside contact opening(s) 214 may be formed by the same or shared lithography and etch process(es), or sequential lithography and etch processes. In such process(es), a mask (not shown) may be applied to the backside of the semiconductor IC device 100 and patterned. Openings in the patterned mask may sequentially expose the portion(s) of the underlying backside ILD 210. Using the patterned mask an etchant may remove the exposed portions of the ILD 210 and may expose the inline backside contact placeholder 178 and may further partially expose the STI region 130 and the isolation pillar 120. The etch may be selective to the respective material(s) of the STI regions 130, to the backside contact placeholder 178, and to the isolation pillar 120. A respective backside contact opening 214 may be formed to expose the associated inline backside contact placeholder 178 there above (e.g., the backside contact placeholder 178 that is below a S/D region 180 that is not connected to the frontside BEOL network 196).

Subsequently, the backside contact placeholders 178 that are exposed by a respective backside contact opening 214 may be removed by a substrative removal technique, such as an etch. In one example, the entire applicable contact placeholders 178 may be removed thereby exposing at least a portion of the S/D region 180 there above. Optionally, the exposed S/D region 180 may be at least partially gouged.

FIG. 17 depicts cross-sectional views of semiconductor IC device 100 shown after illustrative fabrication operation(s), in accordance with one or more embodiments. In the depicted fabrication stage, backside contact(s) 216 may be formed within a respective backside contact opening 214 and a backside BEOL network 270 may be formed.

Respective backside contacts 216 may be formed within a respective backside contact opening 214 by depositing conductive material, such as metal, into the respective backside contact opening(s) 214. In an example, backside contact(s) 216 may be simultaneously formed by depositing a liner, such as Ni, NiPt or Ti, etc. onto the backside of semiconductor IC device 100 and into the backside contact openings 214, depositing an adhesion liner, such as TIN, TaN, etc. upon the liner, and by depositing a conductive fill, such as Al, Ru, W, Co, Cu, etc. upon the adhesion liner. In the depicted illustration, the backside contact 216 may be formed within the backside contact opening 214 directly against the associated exposed S/D region 180.

Subsequently, a planarization process, such as a CMP, may expose a bottom surface of the backside ILD 210. As a result, the respective backside or bottom surfaces of backside contact(s) 216 and backside ILD 210 may be substantially horizontal and/or substantially coplanar.

The backside BEOL network 270, such as a backside power distribution network (BSPDN) may be formed upon the backside contact(s) 216 and upon the backside ILD 210. The backside BEOL network 270 may include signal wires for signal routing and power wires for providing power potential (e.g., VDD, VSS, etc.). The backside BEOL network 270 may allow for the distribution of power wires and signal wires between both the frontside and backside of the semiconductor IC device. The backside BEOL network 270 may further allow for the full or partial decoupling of signal routing and/or power routing and/or allows for dividing or splitting power wires and/or signal wires between both the frontside and backside of the semiconductor IC device. By incorporating the backside BEOL network 270, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 270 may be indirectly electrically and/or indirectly physically connected to the one or more S/D regions 180 by way of a combination of the backside contact 216. The backside BEOL network 270 can include one or more dielectric material layers and contains backside conductive wires and/or interconnects, such as VIAs, embedded therein. In some embodiments, the backside wires within the backside BEOL network 270 are composed of Cu. The backside BEOL network 270 can include “x” numbers of backside metal levels, wherein “x” is an integer starting from 1. If not included in frontside BEOL network 196, backside BEOL network 270 may further contain conductive pads that are connected to one or more of the backside metal wires and may be used to connect the semiconductor IC device 100 to the external and/or higher-level structure.

In an example, signal routing and power routing is effectively split between the frontside BEOL network 196 and the backside BEOL network 270. For example, at least 90% of the frontside metal wires (e.g., furthest from the transistors 100.2, 100.4, 100.6, 100.8, and 100.10) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires and the remainder backside metal wires which are usually present in metal levels furthest away from the backside contacts, can be used as signal routing wires. Power routing wires may be less dense than signal routing wires. A signal routing wire is defined herein as a conductive feature, such as a wire, interconnect, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

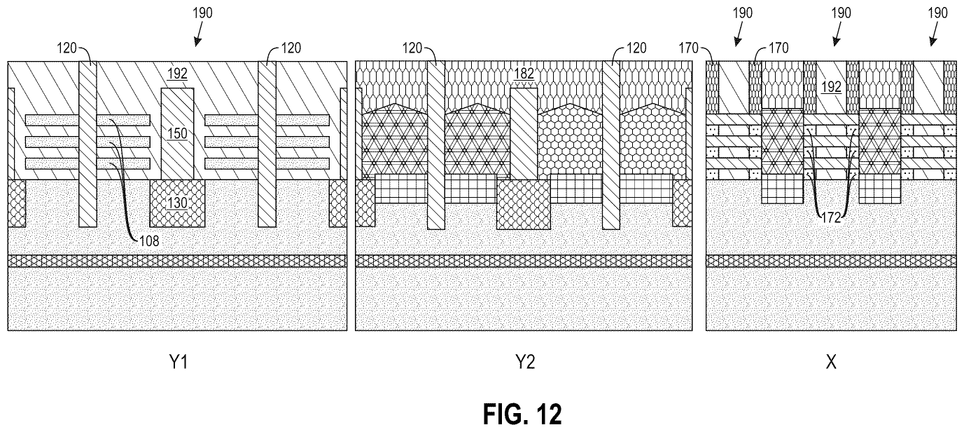

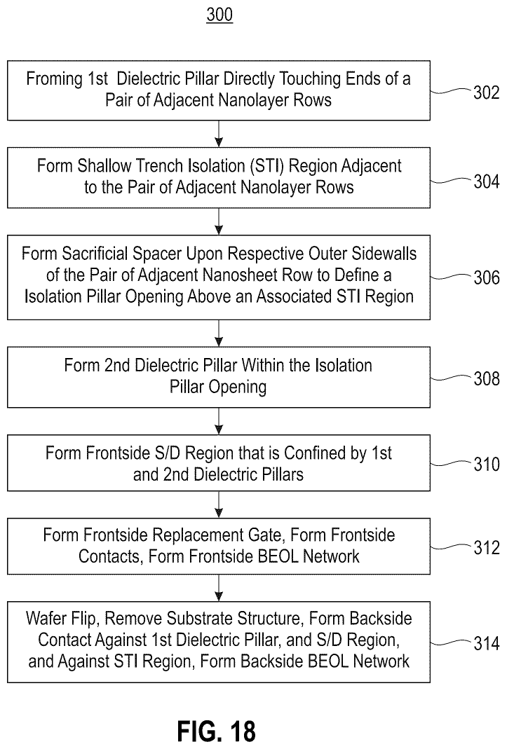

FIG. 18 depicts a flow diagram illustrating a method 300 to fabricate a semiconductor IC device, such as semiconductor IC device 100, though the fabrication operations described in method 300 may be used to fabricate other types of semiconductor IC devices. The depicted fabrication operations of method 300 may be illustratively depicted and described with reference to one or more of FIG. 3 through FIG. 17 of the drawings. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming nanolayers, such as sacrificial nanolayers 106 and active nanolayers 108, upon a substrate structure 102 and patterning the nanolayers into nanolayer rows 109. Block 302 also may include forming isolation pillar 120 between the pair of nanolayer rows 109. At block 304, method 300 may continue with forming STI region 130 adjacent to the pair of nanosheet rows 109.

At block 306, method 300 may continue with forming sacrificial spacer 140 upon respective outers sidewalls of the pair of adjacent nanolayer rows 109 to define an isolation pillar opening 142 that is generally above an STI region 130. At block 308, method 300 may continue with forming isolation pillar 150 within the isolation pillar opening 142.

At block 310, method 300 may continue with forming S/D canyons 175 that separate the nanosheet rows 109 into nanosheet stacks and with forming S/D region 180 within a S/D canyon 175 against or confined by the isolation pillar 120 and the isolation pillar 150.

At block 312, method 300 may continue with forming replacement gate 190, with forming frontside contacts 194, and with forming the frontside BEOL network 196. At block 314, method 300 may continue with flipping the semiconductor IC device, with removing the substrate structure 102, and with forming a backside contact 216 against the isolation pillar 120, against the S/D region 180, and against the STI region 130. Block 314 may further include forming backside BEOL network 270.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first isolation pillar and a second isolation pillar; and
a source/drain region in direct contact with the first isolation pillar and in direct contact with the second isolation pillar.

2. The semiconductor IC device of claim 1, wherein a top surface of the first isolation pillar is above a top surface of the second isolation pillar.

3. The semiconductor IC device of claim 2, wherein a bottom surface of the first isolation pillar is below a bottom surface of the second isolation pillar.

4. The semiconductor IC device of claim 3, further comprising:
a plurality of nanosheet channels each in direct contact with the source/drain region and each in direct contact first isolation pillar.

5. The semiconductor IC device of claim 4, further comprising:
a gate structure in direct contact with the plurality of nanosheet channels, in direct contact with the first isolation pillar, and in direct contact with the second isolation pillar.

6. The semiconductor IC device of claim 5, wherein the top surface of the first isolation pillar is substantially coplanar with a top surface of the gate structure.

7. The semiconductor IC device of claim 6, further comprising:
a shallow trench isolation (STI) region below the second isolation pillar.

8. The semiconductor IC device of claim 7, further comprising:
a backside contact in direct contact with the source/drain region, in direct contact with the first isolation pillar, and in direct contact with the STI region.

9. The semiconductor IC device of claim 1, wherein the first isolation pillar is composed of a first dielectric material and wherein the second isolation pillar is composed of a second dielectric material that is different than the first dielectric material.

10. A semiconductor integrated circuit (IC) device comprising:
a first transistor comprising a first source/drain region and a plurality of first nanosheet channels;
a second transistor comprising a second source/drain region;
a first isolation pillar in direct contact with the first source/drain region and in direct contact with each of the plurality of first nanosheet channels; and
a second isolation pillar in direct contact with the first source/drain region and in direct contact with the second source/drain region.

11. The semiconductor IC device of claim 10, wherein a top surface of the first isolation pillar is above a top surface of the second isolation pillar.

12. The semiconductor IC device of claim 11, wherein a bottom surface of the first isolation pillar is below a bottom surface of the second isolation pillar.

13. The semiconductor IC device of claim 12, further comprising:
a plurality of second nanosheet channels each in direct contact with the second source/drain region.

14. The semiconductor IC device of claim 13, further comprising:
a gate structure in direct contact with the plurality of first nanosheet channels, in direct contact with the plurality of second nanosheet channels, in direct contact with the first isolation pillar, and in direct contact with the second isolation pillar.

15. The semiconductor IC device of claim 14, wherein the top surface of the first isolation pillar is substantially coplanar with a top surface of the gate structure.

16. The semiconductor IC device of claim 15, further comprising:
a shallow trench isolation (STI) region below the second isolation pillar.

17. The semiconductor IC device of claim 16, further comprising:
a first backside contact in direct contact with the first source/drain region, in direct contact with the first isolation pillar, and in direct contact with the STI region.

18. The semiconductor IC device of claim 10, wherein the first isolation pillar is composed of a first dielectric material and wherein the second isolation pillar is composed of a second dielectric material that is different than the first dielectric material.

19. A semiconductor integrated circuit (IC) device comprising:
a first source/drain region;
a second source/drain region;
a first isolation pillar in direct contact with a first sidewall of the first source/drain region;
a second isolation pillar in direct contact with a second sidewall of the first source/drain region and in direct contact with a first sidewall of the second source/drain region; and
a third isolation pillar in direct contact with a second sidewall of the second source/drain region.

20. The semiconductor IC device of claim 19, wherein a bottom surface of the first isolation pillar is below a bottom surface of the second isolation pillar and wherein the bottom surface of the first isolation pillar is substantially coplanar with a bottom surface of the third isolation pillar.
